(19) United States
(12) Patent Application Publication
(10) Pub. No.: US 2025/0208513 A1
(43) Pub. Date: Jun. 26, 2025

(54) EUV LIGHT SOURCE, EUV LITHOGRAPHY APPARATUS, AND METHOD FOR GENERATING EUV LIGHT

(71) Applicant: SAMSUNG ELECTRONICS CO., LTD., Suwon-si (KR)

(72) Inventors: Kyungwan YOO, Suwon-si (KR); Changmin PARK, Suwon-si (KR)

(73) Assignee: SAMSUNG ELECTRONICS CO., LTD., Suwon-si (KR)

(21) Appl. No.: 18/764,686

(22) Filed: Jul. 5, 2024

(30) Foreign Application Priority Data
Dec. 26, 2023 (KR) 10-2023-0191464

(51) Int. Cl. G03F 7/20; G03F 7/00

(52) U.S. Cl. CPC G03F 7/2004; G03F 7/70025; G03F 7/70033

(57) ABSTRACT

An EUV light source includes: a vacuum chamber including a target area, a main generator configured to drop a main droplet into the target area; a laser source configured to irradiate, to the target area, a laser beam that strikes the main droplet to generate plasma; a mirror adjacent to the target area and configured to concentrate extreme ultraviolet rays generated from the plasma, and an additional generator adjacent to the main generator and configured to drop an additional droplet into the target area.

### CROSS-REFERENCE TO RELATED APPLICATION

This application claims priority to Korean Patent Application No. 10-2023-0191464, filed on Dec. 26, 2023 in the Korean Intellectual Property Office, the disclosure of which is incorporated by reference herein in its entirety.

### BACKGROUND

### 1. Field

The present disclosure relates to an extreme ultraviolet light (EUV) light source, an EUV lithography apparatus, and a method for generating EUV light.

### 2. Description of Related Art

In general, an EUV lithography apparatus is a device that performs photolithography on a processing target, such as a semiconductor wafer, using extreme ultraviolet light (EUV).

An EUV lithography apparatus in the related art generates plasma by a laser beam striking on a droplet dropped on a target area in a vacuum chamber, and includes an EUV light source including a mirror that focuses extreme ultraviolet rays generated from the plasma.

However, the related art EUV lithography apparatus has a problem in that droplet debris generated after a laser beam strikes the droplet contaminates the mirror.

### SUMMARY

One or more example embodiments of the present disclosure provide an EUV light source, an EUV lithography apparatus, and a method for generating EUV light in which contamination, by droplet debris, of a mirror, an optical system, a mask, and a wafer, is suppressed.

According to an aspect of an example embodiment, an extreme ultraviolet light (EUV) light source includes: a vacuum chamber including a target area; a main generator configured to drop a main droplet into the target area; a laser source configured to irradiate, to the target area, a laser beam that strikes the main droplet to generate plasma; a mirror adjacent to the target area and configured to concentrate extreme ultraviolet rays generated from the plasma; and a first additional generator adjacent to the main generator and configured to drop a first additional droplet into the target area.

According to an aspect of an example embodiment, an extreme ultraviolet light (EUV) lithography apparatus includes: a vacuum chamber including a target area; a main generator configured to drop a main droplet into the target area; a laser source configured to irradiate, to the target area, a laser beam that strikes the main droplet to generate plasma; a mirror adjacent to the target area and configured to concentrate extreme ultraviolet rays, generated from the plasma, to a focusing point; an additional generator adjacent to the main generator and configured to drop an additional droplet into the target area; and an optical system provided at the focusing point.

According to an aspect of an example embodiment, a method of extreme ultraviolet light (EUV) light generation includes: dropping a main droplet into a target area; irradiating, to the target area, a laser beam that strikes the main droplet to generate plasma; concentrating extreme ultraviolet rays generated from the plasma; and dropping an additional droplet into the target area.

### BRIEF DESCRIPTION OF THE DRAWINGS

The above and other aspects and features will be more apparent from the following description of one or more example embodiments taken in conjunction with the accompanying drawings, in which:

FIG. 1 is a diagram showing an EUV lithography apparatus according to one or more example embodiments;

FIG. 2 is a diagram illustrating an example of a main droplet and a first additional droplet entering a target area of an EUV lithography apparatus according to one or more example embodiments;

FIG. 3 is a diagram illustrating an example in which debris generated from a main droplet is adsorbed by a first additional droplet in a target area of an EUV lithography apparatus according to one or more example embodiments;

FIG. 4 is a diagram showing an EUV lithography apparatus according to one or more example embodiments;

FIG. 5 is a diagram illustrating an example of a main droplet and a first additional droplet entering a target area of an EUV lithography apparatus according to one or more example embodiments;

FIG. 6 is a diagram showing an EUV lithography apparatus according to one or more example embodiments;

FIG. 7 is a diagram illustrating an example of a main droplet and a first additional droplet entering a target area of an EUV lithography apparatus according to one or more example embodiments;

FIG. 8 is a diagram showing an EUV lithography apparatus according to one or more example embodiments;

FIG. 9 is a diagram illustrating an example of a main droplet and a first additional droplet entering a target area of an EUV lithography apparatus according to one or more example embodiments;

FIG. 10 is a diagram showing an EUV lithography apparatus according to one or more example embodiments;

FIG. 11 is a diagram illustrating an example of a main droplet and a first additional droplet entering a target area of an EUV lithography apparatus according to one or more example embodiments;

FIG. 12 is a diagram showing an EUV lithography apparatus according to one or more example embodiments;

FIG. 13 is a diagram showing an EUV lithography apparatus according to one or more example embodiments;

FIG. 14 is a diagram illustrating an example of a main droplet, a first additional droplet, and a second additional droplet entering a target area of an EUV lithography apparatus according to one or more example embodiments;

FIG. 15 is a diagram illustrating top and side views showing examples of collisions between a first additional droplet and a second additional droplet in an EUV lithography apparatus according to one or more example embodiments;

FIG. 16 is a diagram illustrating top and side views showing examples of additional droplets formed after a first additional droplet and a second additional droplet collide in an EUV lithography apparatus according to one or more example embodiments;

FIG. 17 is a diagram showing an EUV lithography apparatus according to one or more example embodiments;

FIG. 18 is a flowchart showing an EUV light-generation method according to one or more example embodiments; and

FIG. 19 is a diagram showing an EUV light-generation method according to one or more example embodiments.

### DETAILED DESCRIPTION

Hereinafter, with reference to the attached drawings, various example embodiments of the present disclosure will be described in detail.

Embodiments of the disclosure may be implemented in many different forms and is not limited to the embodiments described herein. In order to clearly explain the present disclosure, parts that are not relevant to the description, or are duplicative, are omitted, and identical or similar components are assigned the same reference numerals throughout the specification.

In addition, the size and thickness of each component shown in the drawings are arbitrarily shown for convenience of explanation, so the present disclosure is not necessarily limited to that which is shown. In the drawings, the thickness is enlarged to clearly express various layers and regions. And in the drawings, for convenience of explanation, the thicknesses of some layers and regions may be exaggerated.

Additionally, when one part is said to be “above” or “on” another part, this includes not only the case where it is “directly above” the other part, but also the case where there is another part in between. Conversely, when a part is said to be “directly on top” of another part, it means that there is no other part in between. In addition, being “above” or “on” a reference part means being located above or below the reference part, and does not necessarily mean being located “above” or “on” it in the direction opposite to gravity.

In addition, throughout the specification, when a part is said to “include” a certain component, this means that it may further include other components rather than excluding other components, unless specifically stated to the contrary.

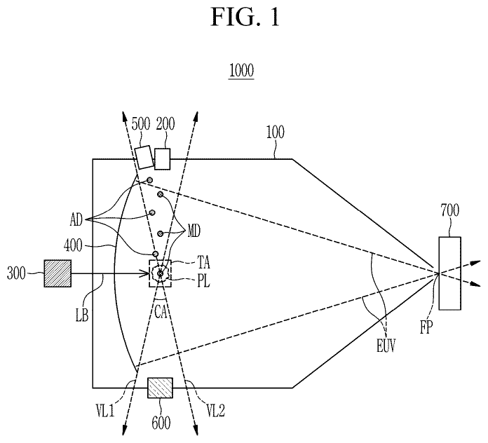

Hereinafter, an EUV lithography apparatus according to one or more example embodiments will be described with reference to FIGS. 1, 2 and 3.

The EUV lithography apparatus according to one or more example embodiments may include a device that performs photolithography on a semiconductor wafer using extreme ultraviolet EUV light, but one or more example embodiments are not limited thereto, and one or more example embodiments may include a device that performs photolithography on various treated bodies.

FIG. 1 is a diagram showing an EUV lithography apparatus according to one or more example embodiments. FIG. 1 may be a side view of an EUV lithography apparatus according to one or more example embodiments, but is not limited thereto and may be a top view or a front view of the EUV lithography apparatus according to one or more example embodiments.

Referring to FIG. 1, the EUV lithography apparatus 1000 according to one or more example embodiments includes a vacuum chamber 100, a main generator 200, a laser source 300, a mirror 400, a first additional generator 500, a droplet catcher 600, and an optical system 700.

The vacuum chamber 100 includes a target area TA therein. The target area TA includes an area where the main droplet MD dropped from the main generator 200 is struck by the laser beam LB emitted from the laser source 300. According to one or more example embodiments, the main droplet MD struck by the laser beam LB in the target area TA of the vacuum chamber 100 may generate plasma PL. Extreme ultraviolet light EUV generated from the plasma PL generated in the target area TA may be focused to the focusing point FP by the mirror 400. Extreme ultraviolet light EUV concentrated at the focusing point FP may be irradiated on a target object such as a semiconductor wafer through the optical system 700 located at the focusing point FP. According to one or more example embodiments, extreme ultraviolet light EUV irradiated from the EUV lithography apparatus 1000 to the object to be processed may expose the photoresist material coated on the object to be processed through various masks, but is not limited thereto. The vacuum chamber 100 may have various forms capable of concentrating extreme ultraviolet light EUV.

The main generator 200 is located in a portion of the vacuum chamber 100. The main generator 200 may drop the main droplet MD into the target area TA of the vacuum chamber 100. The main generator 200 may include, but is not limited to, various nozzles that spray a plurality of main droplets MD in the form of a droplet stream into the target area TA of the vacuum chamber 100. The main droplet MD entering the target area TA from the main generator 200 is struck by the laser beam LB to generate plasma PL. According to one or more example embodiments, the main droplet MD dropped from the main generator 200 to the target area TA may be synchronized with the laser beam LB irradiated from the laser source 300 and the laser beam may be irradiated on the target area TA. The target area TA may be entered by the main droplets MD at the same time as the laser beam LB, but is not limited thereto. The main droplet MD dropped from the main generator 200 may include tin, but is not limited thereto.

The laser source 300 may be located at the center of the mirror 400 and may irradiate the laser beam LB on the target area TA of the vacuum chamber 100. The laser beam LB irradiated from the laser source 300 on the target area TA may strike the main droplet MD to generate plasma PL. The laser beam LB emitted from the laser source 300 may include, but is not limited to, a CO₂ pulse laser beam. According to one or more example embodiments, the laser beam LB irradiated from the laser source 300 on the target area TA may be synchronized with the main droplet MD dropped from the main generator 200 to the target area TA, and the laser beam LB may be irradiated on the target area TA at the same time as the laser beam LB may enter the target area TA, but one or more example embodiments are not limited thereto.

The mirror 400 may be adjacent to the target area TA. According to one or more example embodiments, the center of the mirror 400 may correspond to the target area TA, but one or more example embodiments are not limited thereto. The mirror 400 may focus extreme ultraviolet light EUV generated from the plasma PL generated in the target area TA to the focusing point FP. The mirror 400 may include, but is not limited to, various reflective optical systems. The mirror 400 may include, but is not limited to, a concave mirror. A through hole through which the laser beam LB emitted from the laser source 300 may pass may be formed at the center of the mirror 400, but the present disclosure is not limited thereto.

The first additional generator 500 may be adjacent to the main generator 200. The first additional generator 500 may be located in another part of the vacuum chamber 100. The first additional generator 500 drops the first additional droplet AD into the target area TA of the vacuum chamber 100. The first additional generator 500 may include various nozzles that spray a plurality of first additional droplets AD in the form of a droplet stream into the target area TA of the vacuum chamber 100, but one or more example embodiments are not limited thereto. The first additional droplet AD entering the target area TA from the first additional generator 500 may enter the target area TA at a different time from the main droplet MD entering the target area TA from the main generator 200. The first additional droplet AD entering the target area TA from the first additional generator 500 may not be struck by the laser beam LB emitted from the laser source 300 and may pass through the target area TA.

Debris DE from the main droplet MD generated from the main droplet MD being struck by the laser beam LB in the target area TA may be attached to the first additional droplet AD passing through the target area TA, and such debris DE may be adsorbed and pass through the target area TA together with the first additional droplet AD. According to one or more example embodiments, the first additional droplet AD dropped from the first additional generator 500 to the target area TA may be irradiated in the target area TA in synchronization with the laser beam LB irradiated from the laser source 300, and it may enter the target area TA at a time different from that of the laser beam LB, but one or more example embodiments are not limited thereto. The first additional droplet AD dropped from the first additional generator 500 may include the same tin as the main droplet MD, but one or more example embodiments are not limited thereto, and the first additional droplet AD may comprise a material different from the main droplet MD.

According to one or more example embodiments, the first additional droplet AD may include at least one of polymer, plastic, glass, quartz, dielectric material, semiconductor, silicon, germanium, ceramic, metal, and metal alloy.

According to one or more example embodiments, the first additional droplet AD may include at least one of a metal (e.g., alloy) and a non-metal (e.g., glass, polymer, ceramic), that is, in a solid state at room temperature.

According to one or more example embodiments, the first additional droplet AD may include at least one of metals and ceramics including gold, silver, copper, aluminum, etc.

According to one or more example embodiments, the first additional droplet AD may have the same diameter as the main droplet MD, but one or more example embodiments are not limited thereto and the first additional droplet AD may have a diameter that is different from the main droplet MD. For instance, according to one or more example embodiments, the first additional droplet AD may have a larger diameter than the main droplet MD. For instance, according to one or more example embodiments, the first additional droplet AD may have a smaller diameter than the main droplet MD.

The first additional generator 500 may generate a target and a first virtual line VL1 connecting one end of the mirror 400 and the center of the target area TA where the main droplet MD may be struck by the laser beam LB, and it may be located within the pier CA where the second virtual line VL2 connecting the center of the target area TA and the other end of the mirror 400 intersect. According to one or more example embodiments, the pier CA may be from 20 degrees to 200 degrees, but one or more example embodiments are not limited thereto. The main generator 200 may be located corresponding to the center of the pier CA, but one or more example embodiments are not limited thereto.

According to one or more example embodiments, the first additional generator 500 may include a plurality of first additional generators 500. Each of the plurality of first additional generators 500 may be located in different parts of the vacuum chamber 100 and may drop a plurality of first additional droplets AD into the target area TA.

The vacuum chamber 100, the main generator 200, the laser source 300, the mirror 400, and the first additional generator 500 may be included in the EUV light source that generates extreme ultraviolet light EUV, but one or more example embodiments are not limited thereto. The EUV light source may include a vacuum chamber 100, a main generator 200, a laser source 300, a mirror 400, and a first additional generator 500.

The droplet catcher 600 may be spaced apart from the main generator 200 with the target area TA in between. The droplet catcher 600 may accommodate at least one of the main droplet MD, debris DE from the main droplet MD, and the first additional droplet AD that passed through the target area TA. The droplet catcher 600 may include various droplet-receiving means.

As an example, according to one or more example embodiments, the droplet catcher 600 may include a plurality of droplet catchers 600. A plurality of droplet catchers 600 may each be located in different subparts of the vacuum chamber 100 and may accommodate at least one main droplet MD that may pass through or does not pass through the target area TA, the debris DE from the main droplet MD, and the first additional droplet AD.

According to one or more example embodiments, the droplet catcher 600 may be connected to at least one of the main generator 200 and the first additional generator 500. At least one of the main droplet MD, the debris DE from the main droplet MD, and the first additional droplet AD received by the droplet catcher 600 may be transferred from the droplet catcher 600 to at least one of the main generator 200 and the first additional generator 500 and may be recycled.

The optical system 700 may be located at the focusing point FP. The optical system 700 may include various optical systems, such as a smayner. The optical system 700 may irradiate extreme ultraviolet light EUV focused to a focusing point FP by the mirror 400 to a processing target, such as a semiconductor wafer. According to one or more example embodiments, extreme ultraviolet light EUV that passes through the optical system 700 of the EUV lithography apparatus 1000 and is irradiated on a target object such as a semiconductor wafer, may pass through various masks to expose the photoresist material coated on the target object. However, embodiments are not limited thereto.

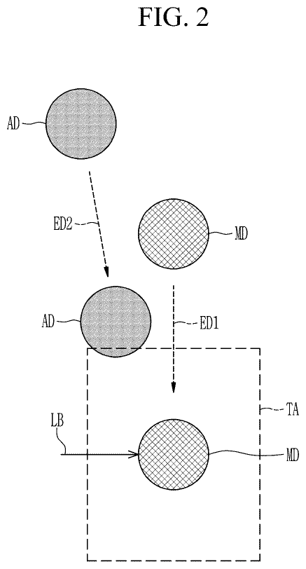

FIG. 2 is a diagram illustrating an example of a main droplet MD and a first additional droplet AD entering a target area of an EUV lithography apparatus according to one or more example embodiments.

Referring to FIG. 2, the main entry direction ED1 of the plurality of main droplets MD sequentially entering the target area TA, may be different from the first entry direction ED2 of the plurality of first additional droplets AD sequentially entering. Based on the irradiation direction of the laser beam LB irradiated on the target area TA, the main entry direction ED1 of the plurality of main droplets MD may be similar to, or the same as, the first entry direction ED2 of the plurality of first additional droplets AD, but embodiments are not limited thereto.

A plurality of main droplets MD sequentially entering the target area TA may be struck by the laser beam LB irradiated on the target area TA at the same times as the plurality of main droplets MD, to generate plasma. According to one or more example embodiments, the plurality of main droplets MD dropped into the target area TA may be synchronized with the laser beam LB irradiated on the target area TA so that the plurality of main droplets MD enter the target area TA at the same time as the laser beam LB irradiated on the target area TA, but embodiments are not limited thereto.

The plurality of first additional droplets AD sequentially entering the target area TA may enter the target area TA at different times from the plurality of main droplets MD and may not be struck by the laser beam LB irradiated on the target area TA, and may pass through the target area TA. According to one or more example embodiments, the plurality of first additional droplets AD dropped into the target area TA may be synchronized with the laser beam LB irradiated on the target area TA and the laser beam LB irradiated on the target area TA to enter target area TA at a different time from the laser beam LB. Each of the plurality of first additional droplets AD may enter the target area TA between the plurality of main droplets MD, but embodiments are not limited thereto, and the plurality of first additional droplets AD may enter the target area TA between the plurality of main droplets MD, and it may be possible to enter the target area TA between droplets MD.

Debris DE from the plurality of main droplets MD generated from the plurality of main droplets MD being sequentially struck by the laser beam LB in the target area TA may sequentially pass through the target area TA, and may be adsorbed by the plurality of first additional droplets AD and pass through the target area TA together with the plurality of first additional droplets AD.

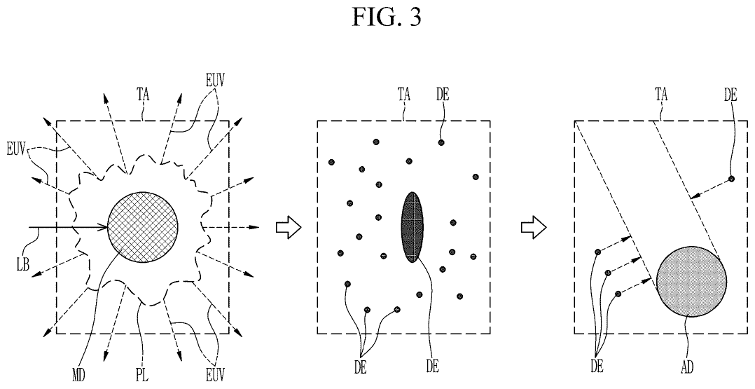

FIG. 3 is a diagram illustrating an example in which debris generated from a main droplet MD is adsorbed by a first additional droplet AD in a target area TA of an EUV lithography apparatus according to one or more example embodiments.

Referring to FIG. 3, the main droplet MD that has been dropped into and has entered the target area TA may be struck by the laser beam LB directed at the target area TA, thereby generating plasma PL. Extreme ultraviolet light EUV generated from the plasma PL may be emitted outside the target area TA and may be focused by a mirror. Debris DE from the main droplet MD remains in the target area TA due to the impact of the main droplet MD being struck by the laser beam LB in the target area TA. The first additional droplet AD, which is dropped into the target area TA and may enter the target area TA at a different time from the main droplet MD, may adsorb the debris DE located in the target area TA, may remove the debris DE, and may pass through the target area TA together with the debris DE.

According to one or more example embodiments, the debris DE from the main droplet MD may be located outside the target area TA, and the first additional droplet AD may pass through the outside of the target area TA to adsorb the debris DE located outside the target area TA.

The first additional droplet AD may adsorb the debris DE separated from the main droplet MD generating the plasma PL, thereby suppressing the debris DE from contaminating the mirror.

According to one or more example embodiments, by adsorbing the debris DE separated from the main droplet MD where the additional volume AD1 generates plasma PL, it may be possible to suppress the contamination of the mirror, optical system, mask, and wafer, by the debris DE.

Furthermore, the first additional droplet AD may adsorb the debris DE separated from the previous main droplet MD that generated plasma PL in the target area TA and that passed through the target region TA, and the extreme ultraviolet light EUV generated from the plasma PL generated from the next main droplet MD in the target area TA may be prevented or suppressed from being absorbed and lost by the debris DE.

According to one or more example embodiments, an EUV light source and an EUV lithography apparatus including the EUV light source may be provided, which suppress the contamination of the mirror by the debris DE from the main droplet MD and the loss of extreme ultraviolet light by the debris DE from the main droplet MD.

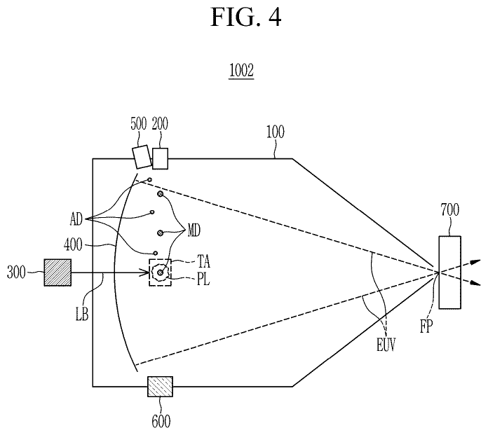

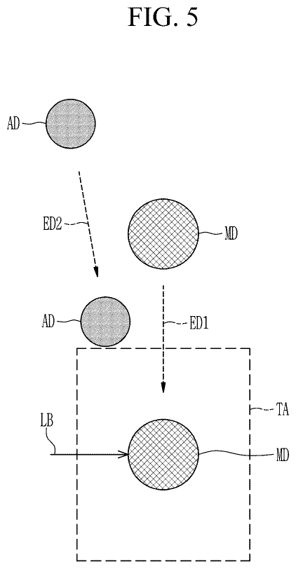

An EUV lithography apparatus according to one or more example embodiments will be described with reference to FIGS. 4 and 5.

Below, parts that are different from the EUV lithography apparatus according to the above-described one or more example embodiments will be described.

FIG. 4 is a diagram showing an EUV lithography apparatus according to one or more example embodiments.

Referring to FIG. 4, the EUV lithography apparatus 1002 according to one or more example embodiments includes a vacuum chamber 100, a main generator 200, a laser source 300, a mirror 400, a first additional generator 500, a droplet catcher 600, and an optical system 700.

FIG. 5 is a diagram illustrating an example of a main droplet MD and a first additional droplet AD entering a target area TA of an EUV lithography apparatus according to one or more example embodiments.

In FIG. 4, and referring to FIG. 5, the first additional generator 500 may drop the first additional droplet AD to the target area TA of the vacuum chamber 100. The first additional generator 500 may include various nozzles to spray a plurality of first additional droplets AD in the form of a droplet stream towards the target area TA of the vacuum chamber 100, but embodiments are not limited thereto. The first additional droplet AD entering the target area TA from the first additional generator 500 may enter the target area TA at a different time from the main droplet MD entering the target area TA from the main generator 200. The first additional droplet AD entering the target area TA from the first additional generator 500 may not be struck by the laser beam LB emitted from the laser source 300 and passing through the target area TA.

Debris DE from the main droplet MD generated from the main droplet MD being struck by the laser beam LB in the target area TA may be attached to the first additional droplet AD passing through the target area TA, and the debris DE may be adsorbed and pass through the target area TA together with the first additional droplet AD. According to one or more example embodiments, the first additional droplet AD dropped from the first additional generator 500 into the target area TA may be irradiated on the target area TA in synchronization with the laser beam LB irradiated from the laser source 300, and it may enter the target area TA at a time different from that of the laser beam LB, but embodiments are not limited thereto. The first additional droplet AD dropped from the first additional generator 500 may include the same tin as the main droplet MD, but embodiments are not limited thereto, and the first additional droplet AD may comprise a material different from the main droplet MD.

The first additional generator 500 drops the first additional droplet AD, which has a smaller diameter than the main droplet MD dropped from the main generator 200, into the target area TA. According to one or more example embodiments, the diameter of the first additional droplet AD may be 0.1% to 99.9% of the diameter of the main droplet MD, but one or more example embodiments are not limited thereto. According to one or more example embodiments, the diameter of the main droplet MD may be 30 μm, and the diameter of the first additional droplet AD may be 0.1 μm, but embodiments are not limited thereto.

The vacuum chamber 100, the main generator 200, the laser source 300, the mirror 400, and the first additional generator 500 may be included in the EUV light source that generates extreme ultraviolet light EUV, but embodiments are not limited thereto. The EUV light source may include a vacuum chamber 100, a main generator 200, a laser source 300, a mirror 400, and a first additional generator 500.

The main entry direction ED1 of the plurality of main droplets MD sequentially entering the target area TA may differ from the first entry direction ED2 of a plurality of first additional droplets AD, which sequentially enter the target area TA at different time than the plurality of main droplets MDs. Based on the irradiation direction of the laser beam LB irradiated on the target area TA, the main entry direction ED1 of the plurality of main droplets MD may be the first entry direction ED2 of the plurality of first additional droplets AD, but embodiments are not limited thereto.

A plurality of main droplets MD, sequentially entering the target area TA, may be struck by a laser beam LB, which is directed at the target area TA at the same times as the plurality of main droplets MD, thereby generating plasma. According to one or more example embodiments, the plurality of main droplets MD dropped into the target area TA may be synchronized with the laser beam LB irradiated on the target area TA and may be identical to the laser beam LB irradiated on the target area TA, and the target area TA may be entered at the right time, but embodiments are not limited thereto.

A plurality of first additional droplets AD sequentially entering the target area TA may enter the target area TA at different times from the plurality of main droplets MD and the first additional droplets AD may not be struck by the laser beam LB irradiated on the target area TA and, the plurality of first additional droplets AD may pass through the target area TA. According to one or more example embodiments, the plurality of first additional droplets AD dropped into the target area TA may be synchronized with the laser beam LB irradiated on the target area TA to enter the target area TA at a time different from that of the laser beam LB irradiated on the target area TA. Each of the plurality of first additional droplets AD may enter the target area TA between the plurality of main droplets MD, but one or more example embodiments are not limited thereto and the plurality of first additional droplets AD may enter the target area TA at times other than between the plurality of main droplets MD.

Debris DE from the plurality of main droplets MD generated from the plurality of main droplets MD being sequentially struck by the laser beam LB in the target area TA may sequentially pass through the target area TA and may be adsorbed by the plurality of first additional droplets AD and may pass through the target area TA together with the plurality of first additional droplets AD.

The diameter of the plurality of first additional droplets AD sequentially entering the target area TA may be smaller than the diameter of the plurality of main droplets MD sequentially entering the target area TA.

According to one or more example embodiments, because the diameters of a plurality of first additional droplets AD may be smaller than those of the plurality of main droplets MD entering the target area TA sequentially, interference between the first entry direction ED2 of the plurality of first additional droplets AD and the main entry direction ED1 of the plurality of main droplets MD may be minimized, therefore, the first entry direction ED2 of the plurality of first additional droplets AD can be set at various angles relative to the main entry direction ED1 of the plurality of main droplets MD to maximize the absorption of debris DE by the plurality of first additional droplets AD in the target area TA.

The first additional droplet AD may adsorb the debris DE separated from the main droplet MD generating the plasma PL, thereby suppressing the debris DE from contaminating the mirror.

According to one or more example embodiments, the first additional droplet AD may adsorb the debris DE separated from the main droplet MD that generated the plasma PL, thereby suppressing the debris DE from contaminating the mirror, optical system, mask, and wafer.

The first additional droplet AD may absorb debris DE separated from the previous main droplet MD that generated plasma in the target area TA, passing through the target area TA. Therefore, one or more example embodiments may suppress the loss of extreme ultraviolet light generated from the plasma generated from the next main droplet MD in the target area TA, which is absorbed by the debris DE.

According to one or more example embodiments, an EUV light source and an EUV lithography apparatus including the EUV light source may be provided, in which contamination of the mirror by the residue of the main droplet MD may be suppressed, and at the same time, the loss of extreme ultraviolet light by the residue of the main droplet MD may be suppressed.

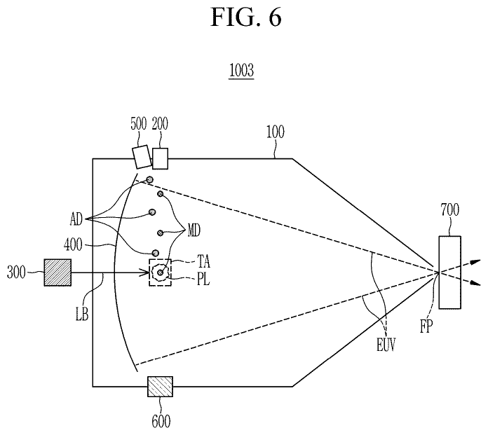

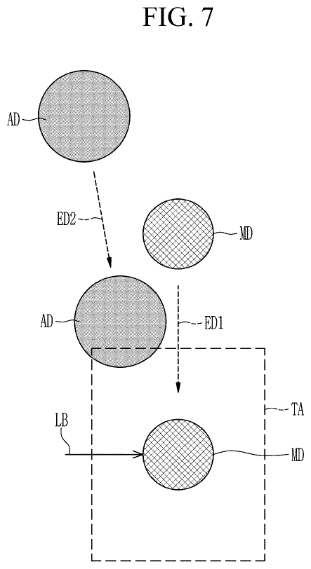

An EUV lithography apparatus according to one or more example embodiments will be described with reference to FIGS. 6 and 7.

Below, parts that are different from the EUV lithography apparatus according to the above-described one or more example embodiments will be described.

FIG. 6 is a diagram showing an EUV lithography apparatus according to one or more example embodiments.

Referring to FIG. 6, the EUV lithography apparatus 1003 according to one or more example embodiments may include a vacuum chamber 100, a main generator 200, a laser source 300, a mirror 400, a first additional generator 500, a droplet catcher 600, and an optical system 700.

FIG. 7 is a diagram illustrating an example of a main droplet MB and a first additional droplet AD entering a target area T of an EUV lithography apparatus according to one or more example embodiments.

Referring to FIGS. 6 and 7, the first additional generator 500 may drop the first additional droplet AD into the target area TA of the vacuum chamber 100. The first additional generator 500 may include various nozzles that spray a plurality of first additional droplets AD in the form of a droplet stream towards the target area TA of the vacuum chamber 100, but embodiments are not limited thereto. The first additional droplet AD entering the target area TA from the first additional generator 500 may enter the target area TA at a different time from the main droplet MD entering the target area TA from the main generator 200. The first additional droplet AD entering the target area TA from the first additional generator 500 may not be struck by the laser beam LB emitted from the laser source 300 and may pass through the target area TA.

Debris DE from the main droplet MD generated from the main droplet being MD struck by the laser beam LB in the target area TA may be attached to the first additional droplet AD passing through the target area TA, and the debris DE may be adsorbed and pass through the target area TA together with the first additional droplet AD. According to one or more example embodiments, the first additional droplet AD dropped from the first additional generator 500 to the target area TA may be irradiated in the target area TA in synchronization with the laser beam LB irradiated from the laser source 300, and it may enter the target area TA at a time different from that of the laser beam LB, but embodiments are not limited thereto. The first additional droplet AD dropped from the first additional generator 500 may include the same tin as the main droplet MD, but embodiments are not limited thereto, and the first additional droplet AD may comprise a material different from the main droplet MD.

The first additional generator 500 drops the first additional droplet AD, which has a larger diameter than the main droplet MD dropped from the main generator 200, into the target area TA. According to one or more example embodiments, the diameter of the first additional droplet AD may be 101% to 40000% of the diameter of the main droplet MD, but embodiments are not limited thereto. According to one or more example embodiments, the diameter of the main droplet MD may be 30 μm, and the diameter of the first additional droplet AD may be 10 mm, but embodiments are not limited thereto.

The vacuum chamber 100, the main generator 200, the laser source 300, the mirror 400, and first additional generator 500 may be included in the EUV light source that generates extreme ultraviolet light EUV, but example embodiments are not limited thereto. The EUV light source may include a vacuum chamber 100, a main generator 200, a laser source 300, a mirror 400, and a first additional generator 500.

The main entry direction ED1 of the plurality of main droplets MD sequentially entering the target area TA may differ from the first entry direction ED2 of the plurality of first additional droplets AD entering the target area TA at different times from the plurality of main droplets MD. Based on the irradiation direction of the laser beam LB irradiated on the target area TA, the main entry direction ED1 of the plurality of main droplets MD may be the first entry direction ED2 of the plurality of first additional droplets AD, but embodiments are not limited thereto.

A plurality of main droplets MD sequentially entering the target area TA may be struck by the laser beam LB irradiated on the target area TA at the same times as the plurality of main droplets MD, to generate plasma. According to one or more example embodiments, the plurality of main droplets MD dropped into the target area TA are synchronized with the laser beam LB irradiated on the target area TA to enter the target area TA at the same time as the laser beam LB irradiated on the target area TA, but embodiments are not limited thereto.

The plurality of first additional droplets AD sequentially entering the target area TA, may enter the target area TA at different times from the plurality of main droplets MD and the laser beam may be irradiated on the target area TA, and the first additional droplets AD may not be not struck by the laser beam LB and pass through the target area TA. According to one or more example embodiments, the plurality of first additional droplets AD dropped into the target area TA may be synchronized with the laser beam LB irradiated on the target area TA and the laser beam LB irradiated on the target area TA, may enter at a time different from that of the plurality of first additional droplets AD, but embodiments are not limited thereto. Each of the plurality of first additional droplets AD may enter the target area TA between the plurality of main droplets MD, but embodiments are not limited thereto and the plurality of first additional droplets AD may enter the target area TA at the same time as the plurality of main droplets MD, so it may be possible to enter the target area TA between the plurality of main droplets MD.

Debris DE from the plurality of main droplets MD generated from the plurality of main droplets MD being sequentially struck by the laser beam LB in the target area TA may sequentially pass through the target area TA and may be adsorbed by the plurality of first additional droplets AD and pass through the target area TA together with the plurality of first additional droplets AD.

The diameter of the plurality of first additional droplets AD sequentially entering the target area TA may be larger than the diameter of the plurality of main droplets MD sequentially entering the target area TA.

According to one or more example embodiments, the diameter of the plurality of first additional droplets AD may be larger than the diameter of the plurality of main droplets MD sequentially entering the target area TA, thereby increasing the passage area of the plurality of first additional droplets AD passing through the target area TA compared to the plurality of main droplets MD and at the same time the attractive force of the plurality of first additional droplets AD increases, and the plurality of first additional droplets AD in the target area TA may improve debris DE adsorption.

The first additional droplet AD may adsorb the debris DE separated from the main droplet MD generating the plasma PL, thereby suppressing the debris DE from contaminating the mirror.

According to one or more example embodiments, by adsorbing the debris DE separated from the main droplet volume MD that generated the plasma PL through the first additional discharge volume AD, the contamination of the mirror, optical system, mask, and wafer by the debris DE may be suppressed.

the first additional droplet AD may absorb the debris DE separated from the previous main droplet MD that generated plasma in the target area TA, and by passing through the target area TA, this may suppress the extreme ultraviolet light generated by the plasma from the next main droplet MD in the target area TA from being absorbed by the debris DE and lost.

In one or more example embodiments, an EUV lithography apparatus comprising an EUV light source and an EUV light source wherein the mirror may be suppressed from being contaminated by debris DE in the main droplet MD and, at the same time, extreme ultraviolet light may be suppressed from being lost to debris DE in the main droplet MD.

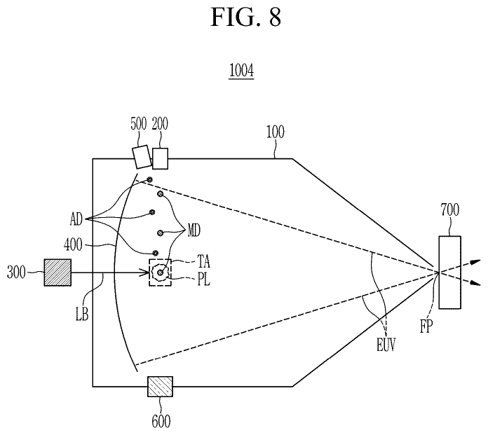

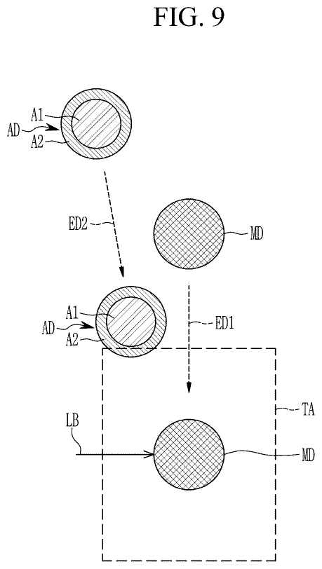

An EUV lithography apparatus according to one or more example embodiments will be described with reference to FIGS. 8 and 9.

Below, parts that are different from the EUV lithography apparatus according to the above-described one or more example embodiments will be described.

FIG. 8 is a diagram showing an EUV lithography apparatus according to one or more example embodiments.

Referring to FIG. 8, an EUV lithography apparatus 1004 according to one or more example embodiments includes a vacuum chamber 100, a main generator 200, a laser source 300, a mirror 400, and a first additional generator 500, and includes a droplet catcher 600 and an optical system 700.

FIG. 9 is a diagram illustrating an example of a main droplet MD and a first additional droplet AD entering a target area TA of an EUV lithography apparatus according to one or more example embodiments.

In FIG. 8, and referring to FIG. 9, the first additional generator 500 drops the first additional droplet AD to the target area TA of the vacuum chamber 100. The first additional generator 500 may include various nozzles to spray a plurality of first additional droplets ADs in the form of a droplet stream into the target area TA of the vacuum chamber 100, but embodiments are not limited thereto. The first additional droplet AD entering the target area TA from the first additional generator 500 may enter the target area TA at a different time from the main droplet MD entering the target area TA from the main generator 200. The first additional droplet AD entering the target area TA from the first additional generator 500 may not be struck by the laser beam LB emitted from the laser source 300 and may pass through the target area TA.

Debris DE from the main droplet MD generated from the main droplet MD being struck by the laser beam LB in the target area TA may be attached to the first additional droplet AD passing through the target area TA, and may be adsorbed and pass through the target area TA together with the first additional droplet AD. According to one or more example embodiments, the first additional droplet AD dropped from the first additional generator 500 to the target area TA may enter the target area TA at a different timing than the laser beam LB irradiated on the target area TA, or synchronized with the laser beam LB irradiated from the laser source 300, but one or more example embodiments are not limited thereto. The first additional droplet AD dropped from the first additional generator 500 may include the same tin as the main droplet MD, but embodiments are not limited thereto, and the first additional droplet AD may comprise a material different from the main droplet MD.

The first additional droplet AD dropped from the first additional generator 500 surrounds the core A1 comprising a different material from the main droplet MD, and a shell A2 surrounding the core A1 and having a higher adsorption capacity with the main droplet MD than with the core A1.

The core A1 may include materials for the size, weight, velocity, and shape of the first additional droplet AD.

According to one or more example embodiments, the core A1 may include at least one of polymer, plastic, glass, quartz, dielectric material, semiconductor, silicon, germanium, ceramic, metal, and metal alloy.

According to one or more example embodiments, the core A1 may include at least one of a metal (e.g., alloy) and a non-metal (e.g., glass, polymer, ceramic) that is in a solid state at room temperature.

According to one or more example embodiments, the core A1 may include at least one of metals and ceramics including gold, silver, copper, aluminum, etc.

The shell A2 may include a material with high chemical affinity for the main droplet MD to facilitate adsorption of debris DE from the main droplet MD.

The shell A2 may contain the same tin as the main droplet MD, but embodiments are not limited thereto and the shell A2 may contain a material that is different from the main droplet MD.

According to one or more example embodiments, the shell A2 may include at least one of polymer, plastic, glass, quartz, dielectric material, semiconductor, silicon, germanium, ceramic, metal, and metal alloy.

According to one or more example embodiments, the shell A2 may include at least one of a metal (e.g., alloy) and a non-metal (e.g., glass, polymer, ceramic) that is in a solid state at room temperature.

According to one or more example embodiments, the shell A2 may include at least one of metals and ceramics including gold, silver, copper, aluminum, etc.

The vacuum chamber 100, main generator 200, laser source 300, mirror 400, and first additional generator 500 may be included in the EUV light source that may generate extreme ultraviolet light EUV, but embodiments are not limited thereto. The EUV light source may include a vacuum chamber 100, a main generator 200, a laser source 300, a mirror 400, and a first additional generator 500.

The main entry direction ED1 of the plurality of main droplets MD sequentially entering the target area TA may differ from the first entry direction ED2 of the plurality of first additional droplets ADs sequentially entering the target area TA at different times from the plurality of main droplets MD. Based on the irradiation direction of the laser beam LB irradiated on the target area TA, the main entry direction ED1 of the plurality of main droplets MD may be the first entry direction ED2 of the plurality of first additional droplets AD, but embodiments are not limited thereto.

A plurality of main droplets MD sequentially entering the target area TA may be struck by the laser beam LB irradiated on the target area TA at the same times as the plurality of main droplets MD, to generate plasma. According to one or more example embodiments, the plurality of main droplets MD dropped into the target area TA may be synchronized with the laser beam LB irradiated on the target area TA to enter the target area TA at the same time as the laser beam LB irradiated on the target area TA, but one or more example embodiments are not limited thereto. A plurality of first additional droplets AD sequentially entering the target area TA may enter the target area TA at different times from the plurality of main droplets MD and may be unstruck by the laser beam irradiated on the target area TA and may pass through the target area TA. According to one or more example embodiments, the plurality of first additional droplets AD dropped into the target area TA may be synchronized with the laser beam LB irradiated on the target area TA to enter the target area TA at a time different than the laser beam LB irradiated on the target area TA. Each of the plurality of first additional droplets AD may enter the target area TA between the plurality of main droplets MD, but embodiments are not limited thereto and the plurality of first additional droplets AD may enter the target area TA at the same time as the plurality of main droplets MD, and it may be possible to enter the target area TA between the main droplets MD.

Debris DE from the plurality of main droplets MD generated from the plurality of main droplets MD being sequentially struck by the laser beam LB in the target area TA may sequentially pass through the target area TA, and it may be adsorbed by the plurality of first additional droplets AD and pass through the target area TA together with the plurality of first additional droplets AD.

Each of the plurality of first additional droplets AD sequentially entering the target area TA may include the core A1 and may have the same size, weight, speed, and shape as the main droplet MD, and each of the plurality of first additional droplets AD may contain a shell A2 with high chemical affinity for the main droplet MD to facilitate debris DE adsorption.

According to one or more example embodiments, each of the plurality of first additional droplets AD may include a core A1 and a shell A2, so that the size, weight, speed, and shape of the plurality of first additional droplets AD passing through the target area TA are improved for debris DE adsorption of the main droplet MD while simultaneously improving the debris DE adsorption capacity of the plurality of first additional droplets AD, and debris DE adsorption capacity by the plurality of first additional droplets AD in the target area TA may be improved.

The first additional droplet AD adsorbs the debris DE separated from the main droplet MD generating the plasma PL, thereby suppressing the debris DE from contaminating the mirror.

According to one or more example embodiments, by the first additional droplet AD adsorbing the debris DE separated from the main droplet MD that generated the plasma PL, the debris DE may be suppressed from contaminating the mirror, optical system, mask, and wafer.

Additionally, the first additional droplet AD may absorb the debris DE separated from the previous main droplet MD that generated plasma in the target area TA, passing through the target area TA, and as a result, the loss of extreme ultraviolet light generated from the plasma produced by the next main droplet MD in the target area TA, which is absorbed by the debris DE, may be suppressed.

According to one or more example embodiments, an EUV light source and an EUV lithography apparatus including the EUV light source, ay be provided, which suppress the contamination of the mirror by the residue of the main droplet MD and the loss of extreme ultraviolet light by the residue of the main droplet MD at the same time.

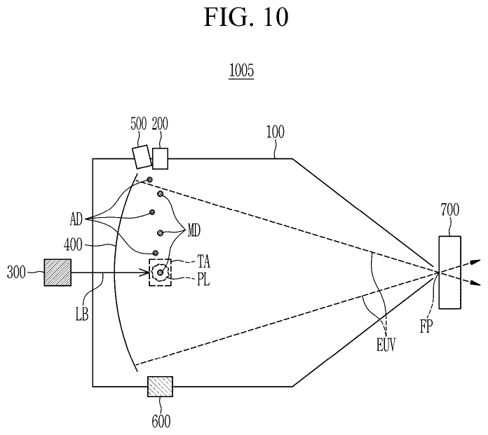

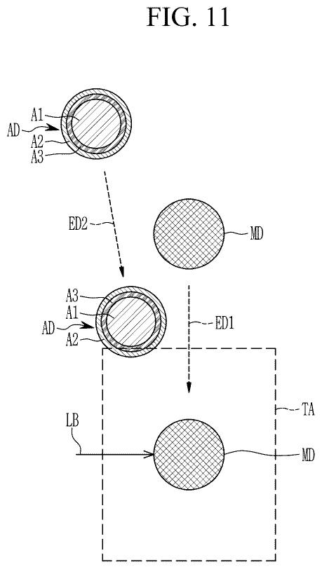

An EUV lithography apparatus according to one or more example embodiments will be described with reference to FIGS. 10 and 11.

Below, parts that are different from the EUV lithography apparatus according to the above-described one or more example embodiments will be described.

FIG. 10 is a diagram showing an EUV lithography apparatus according to one or more example embodiments.

Referring to FIG. 10, an EUV lithography apparatus 1005 according to one or more example embodiments includes a vacuum chamber 100, a main generator 200, a laser source 300, a mirror 400, a first additional generator 500, and includes a droplet catcher 600 and an optical system 700.

FIG. 11 is a diagram illustrating an example of a main droplet MD and a first additional droplet AD entering a target area TA of an EUV lithography apparatus according to one or more example embodiments.

In FIG. 10 and referring to FIG. 11, the first additional generator 500 drops the first additional droplet AD into the target area TA of the vacuum chamber 100. The first additional generator 500 may include various nozzles to spray a plurality of first additional droplets AD into the target area TA of the vacuum chamber 100 in the form of a droplet stream, but embodiments are not limited thereto. The first additional droplet AD entering the target area TA from the first additional generator 500 may enter the target area TA at a different time from the main droplet MD entering the target area TA from the main generator 200. The first additional droplet AD entering the target area TA from the first additional generator 500 may not be struck by the laser beam LB emitted from the laser source 300 and may pass through the target area TA.

Debris DE from the main droplet MD generated from the main droplet MD being struck by the laser beam LB in the target area TA may be attached to the first additional droplet AD passing through the target area TA, and it may be adsorbed and pass through the target area TA together with the first additional droplet AD. According to one or more example embodiments, the first additional droplet AD dropped from the first additional generator 500 into the target area TA may be irradiated on the target area TA in synchronization with the laser beam LB irradiated from the laser source 300. The first additional droplet AD may enter the target area TA at a time different from that of the laser beam LB, but embodiments are not limited thereto. The first additional droplet AD dropped from the first additional generator 500 may include the same tin as the main droplet MD, but embodiments are not limited thereto, and the first additional droplet AD and may comprise a different material than the main droplet MD.

The first additional droplet AD dropped from the first additional generator 500 may comprise a core A1 containing a different material from the main droplet MD, a shell A2 with high adsorption capacity, and an intermediate layer A3 that bonds between the core A1 and the shell A2.

The core A1 may include materials for the size, weight, speed, and shape of the first additional droplet AD.

According to one or more example embodiments, the core A1 may include at least one of polymer, plastic, glass, quartz, dielectric material, semiconductor, silicon, germanium, ceramic, metal, and metal alloy.

According to one or more example embodiments, the core A1 may include at least one of a metal (e.g., alloy) and a non-metal (glass, polymer, ceramic) that is in a solid state at room temperature.

According to one or more example embodiments, the core A1 may include at least one of metals including gold, silver, copper, aluminum, and the like, and ceramics.

According to one or more example embodiments, the shell A2 may include a material with high chemical affinity for the main droplet MD to facilitate adsorption of debris DE from the main droplet MD.

The shell A2 may contain the same tin as the main droplet MD, but one or more example embodiments are not limited thereto and the shell A2 may contain a different material from the main droplet MD.

According to one or more example embodiments, the shell A2 may include at least one of polymer, plastic, glass, quartz, dielectric material, semiconductor, silicon, germanium, ceramic, metal, and metal alloy.

According to one or more example embodiments, the shell A2 may include at least one of a metal (e.g., alloy) and a non-metal (e.g., glass, polymer, ceramic) that is in a solid state at room temperature.

According to one or more example embodiments, the shell A2 may include at least one of metals and ceramics including gold, silver, copper, aluminum, etc.

According to one or more example embodiments, the intermediate layer A3 may include a material with high chemical affinity for the core A1 and the shell A2 so that the core A1 and the shell A2 are easily bonded without separation.

According to one or more example embodiments, the intermediate layer A3 may include at least one of polymer, plastic, glass, quartz, dielectric material, semiconductor, silicon, germanium, ceramic, metal, and metal alloy.

According to one or more example embodiments, the intermediate layer A3 may include at least one of a metal (e.g., alloy) and a non-metal (e.g., glass, polymer, ceramic) that is in a solid state at room temperature.

According to one or more example embodiments, the intermediate layer A3 may include at least one of metals and ceramics including gold, silver, copper, aluminum, etc.

The vacuum chamber 100, the main generator 200, the laser source 300, the mirror 400, and the first additional generator 500 may be included in the EUV light source that may generate extreme ultraviolet light EUV, but embodiments are not limited thereto. The EUV light source may include a vacuum chamber 100, a main generator 200, a laser source 300, a mirror 400, and a first additional generator 500.

The main entry direction ED1 of the plurality of main droplets MD sequentially entering the target area TA may be different from the first entry direction ED2 of the plurality of first additional droplets AD sequentially entering the target area TA at a different time from the plurality of main droplets MD. Based on the irradiation direction of the laser beam LB irradiated on the target area TA, the main entry direction ED1 of the plurality of main droplets MD may intersect with the main entry direction ED2 of the plurality of first additional droplets AD, but embodiments are not limited thereto.

A plurality of main droplets MD sequentially entering the target area TA may be struck by the laser beam LB irradiated on the target area TA at the same times as the plurality of main droplets MD, to generate plasma. According to one or more example embodiments, the plurality of main droplets MD dropped into the target area TA may be synchronized with the laser beam LB irradiated on the target area TA and to enter the target area TA at the same time as the laser beam LB irradiated on the target area TA, but embodiments are not limited thereto.

The plurality of first additional droplets AD sequentially entering the target area TA may enter the target area TA at a different times from the plurality of main droplets MD, and the laser beam may be irradiated on the target area TA, and the additional droplets AD may not be struck by the laser beam LB and may pass through the target area TA. According to one or more example embodiments, the plurality of first additional droplets AD dropped into the target area TA may be synchronized with the laser beam LB irradiated on the target area TA and the laser beam LB may be irradiated on the target area TA at a time different from when the first additional droplets AD enter the target area TA, but embodiments are not limited thereto. Each of the plurality of first additional droplets AD may enter the target area TA between the plurality of main droplets MD, but one or more example embodiments are not limited thereto and the plurality of first additional droplets AD may enter the target area TA at the same time as the plurality of main droplets MD.

Debris DE from the plurality of main droplets MD generated from the plurality of main droplets MD being sequentially struck by the laser beam LB in the target area TA may sequentially pass through the target area TA, and the debris DE may be adsorbed to the plurality of first additional droplets AD and may pass through the target area TA together with the plurality of first additional droplets AD.

Each of the plurality of first additional droplets AD sequentially entering the target area TA may include the core A1 and may have the same size, weight, speed, and shape of as the main droplet MD. Each of the plurality of first additional droplets AD may include a shell A2 with high chemical affinity for the main droplet MD to facilitate debris DE adsorption, and may include an intermediate layer A3 that bonds between the core A1 and the shell A2.

In one example, each of the plurality of first additional droplets AD includes a core A1, a shell A2, and an intermediate layer A3, so that a plurality of first additional droplets AD pass through the target area TA, and the size, weight, speed, and shape of the main droplet MD are improved for debris DE adsorption and the debris DE adsorption ability of the plurality of first additional droplets AD may be improved, and the plurality of first additional droplets AD may also be improved for debris DE adsorption in the target area TA. Because the shell A2 is not separated from the core A1 when dropped into the target area TA, debris DE adsorption by the plurality of first additional droplets AD in the target area TA may be improved.

The first additional droplet AD adsorbs the debris DE separated from the main droplet MD generating the plasma PL, thereby suppressing the debris DE from contaminating the mirror.

According to one or more example embodiments, by adsorbing the debris DE separated from the main droplet MD where the first additional droplet AD generates the plasma PL, the contamination of the mirror, optical system, mask, and wafer by the debris DE may be suppressed.

Also, by absorbing the debris DE separated from the previous main droplet MD that generated plasma in the target area TA using the first additional droplet AD in the target area TA and passing through the target area TA, the loss of extreme ultraviolet light generated from the plasma generated from the next main droplet MD in the target area TA may be suppressed by being absorbed by the debris DE.

According to one or more example embodiments, an EUV light source and an EUV lithography apparatus including the EUV light source may be provided, which suppress contamination of the mirror by the debris DE from the main droplet MD, while simultaneously suppressing loss of extreme ultraviolet light by the debris DE from the main droplet MD.

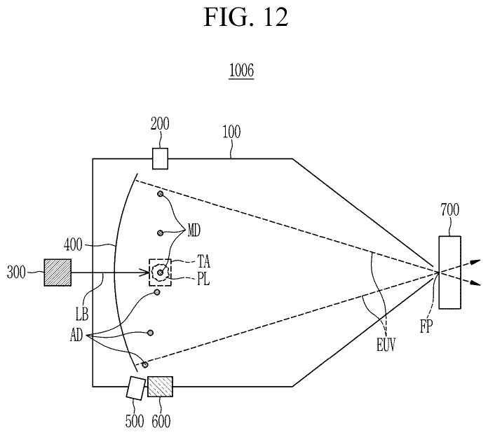

An EUV lithography apparatus according to one or more example embodiments will be described with reference to FIG. 12.

Below, parts that are different from the EUV lithography apparatus according to the above-described one or more example embodiments will be described.

FIG. 12 is a diagram showing an EUV lithography apparatus according to one or more example embodiments.

Referring to FIG. 12, an EUV lithography apparatus 1006 according to one or more example embodiments includes a vacuum chamber 100, a main generator 200, a laser source 300, a mirror 400, a first additional generator 500, a droplet catcher 600 and an optical system 700.

The first additional generator 500 may be spaced apart from the main generator 200 with the target area TA in between. The drop direction of the first additional droplet AD dropped from the first additional generator 500 to the target area TA may be in the opposite direction to the drop direction of the main droplet MD dropped to the target area TA, but embodiments are not limited thereto.

The debris DE from a plurality of main droplets MD, which are sequentially struck by a laser beam LB in the target area TA, may pass through the target area TA along with a plurality of first additional droplets AD, by being absorbed by the plurality of first additional droplets AD that may sequentially pass through the target area TA.

The first additional droplet AD adsorbs the debris DE separated from the main droplet MD generating the plasma PL, thereby suppressing the debris DE from contaminating the mirror.

According to one or more example embodiments, by adsorbing the debris DE separated from the main droplet MD that generated the plasma PL with the first additional droplet AD, the contamination of the mirror, optical system, mask, and wafer, etc. by the debris DE may be suppressed.

Furthermore, the first additional droplet AD may absorb debris DE separated from the previous main droplet MD that generated plasma in the target area TA, and may pass through the target area TA, thereby suppressing the loss of extreme ultraviolet light generated by the plasma generated from the next main droplet MD in the target area TA due to absorption by the debris DE.

According to one or more example embodiments, an EUV light source and an EUV lithography apparatus including the EUV light source may be provided, which suppress contamination of the mirror by the residue of the main droplet MD, while simultaneously suppressing loss of extreme ultraviolet light due to the residue of the main droplet MD.

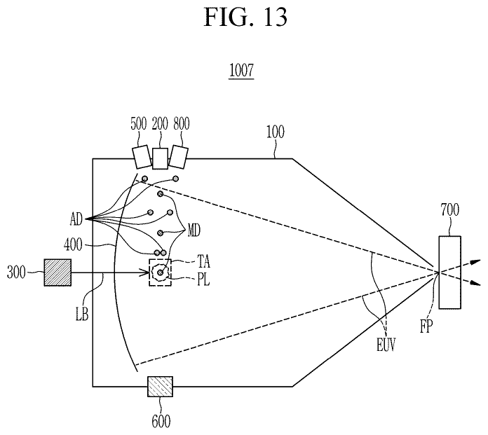

An EUV lithography apparatus according to one or more example embodiments will be described with reference to FIGS. 13, 14, 15 and 16.

Below, parts that are different from the EUV lithography apparatus according to the above-described one or more example embodiments will be described.

FIG. 13 is a diagram showing an EUV lithography apparatus according to one or more example embodiments.

Referring to FIG. 13, an EUV lithography apparatus 1007 according to one or more example embodiments includes a vacuum chamber 100, a main generator 200, a laser source 300, a mirror 400, a first additional generator 500, a droplet catcher 600, an optical system 700, and a second additional generator 800.

The second additional generator 800 may be adjacent to the main generator 200.

The second additional generator 800 may be located in another part of the vacuum chamber 100. The second additional generator 800 may drop the second additional droplet AD into the target area TA of the vacuum chamber 100. The second additional generator 800 may include various nozzles that spray a plurality of second additional droplets AD in the form of a droplet stream to the target area TA of the vacuum chamber 100, but embodiments are not limited thereto. The second additional droplet AD entering the target area TA from the second additional generator 800 may enter the target area TA at a different time from the main droplet MD entering the target area TA from the main generator 200. The second additional droplet AD entering the target area TA from the second additional generator 800 may not be struck by the laser beam LB emitted from the laser source 300 and may pass through the target area TA.

The debris DE from the main droplet MD, which is struck by the laser beam LB in the target area TA, may pass through the target area TA by being absorbed into the second additional droplet AD.

According to one or more example embodiments, the second additional droplet AD dropped from the second additional generator 800 into the target area TA may be irradiated on the target area TA in synchronization with the laser beam LB irradiated from the laser source 300. The second additional droplet AD may enter the target area TA at a time different from that of the laser beam LB, but embodiments are not limited thereto. The second additional droplet AD dropped from the second additional generator 800 may include the same tin as the main droplet MD, but embodiments are not limited thereto, and the second additional droplet AD may comprise a different material from the main droplet MD.

According to one or more example embodiments, the second additional droplet AD may include at least one of polymer, plastic, glass, quartz, dielectric material, semiconductor, silicon, germanium, ceramic, metal, and metal alloy.

According to one or more example embodiments, the second additional droplet AD may include at least one of a metal (e.g., alloy) and a non-metal (e.g., glass, polymer, ceramic) that is in a solid state at room temperature.

According to one or more example embodiments, the second additional droplet AD may include at least one of metals and ceramics including gold, silver, copper, aluminum, etc.

The second additional generator 800 may surround the main generator 200 in a plane along with the first additional generator 500, but embodiments are not limited thereto.

According to one or more example embodiments, the second additional generator 800 may include a plurality of second additional generators 800. Each of the plurality of second additional generators 800 may be located in different parts of the vacuum chamber 100 and may drop a plurality of second additional droplets AD into the target area TA.

The vacuum chamber 100, the main generator 200, the laser source 300, the mirror 400, the first additional generator 500, and the second additional generator 800 are EUV light sources that generate extreme ultraviolet light EUV, but one or more example embodiments are not limited thereto. The EUV light source may include a vacuum chamber 100, a main generator 200, a laser source 300, a mirror 400, a first additional generator 500, and a second additional generator 800.

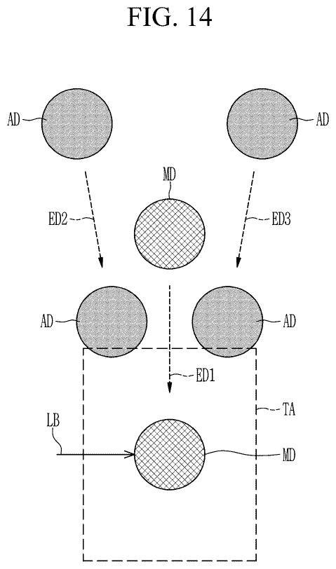

FIG. 14 is a diagram illustrating an example of a main droplet MD, a first additional droplet AD, and a second additional droplet AD entering a target area TA of an EUV lithography apparatus according to one or more example embodiments.

Referring to FIGS. 13 and 14, the first additional generator 500 and the second additional generator 800 may drop the first additional droplet AD and the second additional droplet AD into the target area TA of the vacuum chamber 100. The first additional droplet AD and the second additional droplet AD entering the target area TA from the first additional generator 500 and the second additional generator 800 may enter the target area TA at a different time than the main droplet MD entering the target area TA from the main generator 200. The first additional droplet AD and the second additional droplet AD entering the target area TA from the first additional generator 500 and the second additional generator 800 are may not be struck by the laser beam LB irradiated from the laser source 300, and may pass through the target area TA.

The debris DE from the main droplet MD generated from the main droplet MD being struck by the laser beam LB in the target area TA may be divided into a first additional droplet AD passing through the target area TA, and it may be adsorbed to the second additional droplet AD and pass through the target area TA together with the first additional droplet AD and the second additional droplet AD. For example, the first additional droplet AD and the second additional droplet AD dropped from the first additional generator 500 to the target area TA are synchronized with the laser beam LB irradiated from the laser source 300, and accordingly, the first additional droplet AD and the second additional droplet AD may enter the target area TA at a different time than the laser beam LB irradiated into the target area TA, but embodiments are not limited thereto. The first additional droplet AD dropped from the first additional generator 500 and the second additional droplet AD dropped from the second additional generator 800 may contain the same tin as the main droplet MD. However, the material is not limited thereto, and the first additional droplet AD and the second additional droplet AD may include a different material from the main droplet MD.

The vacuum chamber 100, the main generator 200, the laser source 300, the mirror 400, the first additional generator 500, and the second additional generator 800 are EUV light sources that generate extreme ultraviolet light EUV, but are not limited thereto. The EUV light source may include a vacuum chamber 100, a main generator 200, a laser source 300, a mirror 400, a first additional generator 500, and a second additional generator 800.

The main entry direction ED1 of the plurality of main droplets MD sequentially entering the target area TA may be different from the first entry direction ED2 of the plurality of additional droplets AD and the second entry direction ED3 of the plurality of second additional droplets AD that sequentially enter the target area TA at different times than the plurality of main droplets MD. The main entry direction ED1 of the plurality of main droplets MD, based on the irradiation direction of the laser beam LB being irradiated in the target area TA, can intersect with the first entry direction ED2 of a plurality of first additional droplets AD and the second entry direction ED3 of a plurality of second additional droplets AD, but embodiments are not limited to thereto.

A plurality of main droplets MD sequentially entering the target area TA may be struck by the laser beam LB irradiated on the target area TA at the same times as the plurality of main droplets MD to generate plasma. According to one or more example embodiments, the plurality of main droplets MD dropped into the target area TA may be synchronized with the laser beam LB irradiated on the target area TA to enter the target area TA at the same time as the laser beam LB irradiated on the target area TA, but one or more example embodiments are not limited thereto. A plurality of first additional droplets AD and a plurality of second additional droplets AD may sequentially enter the target area TA at different times from those of the plurality of main droplets MD. Therefore, the plurality of second additional droplets AD may not be struck by the laser beam LB irradiated on the target area TA and may pass through the target area TA. According to one or more example embodiments, a plurality of first additional droplets AD and a plurality of second additional droplets AD dropped into the target area TA may be synchronized with the laser beam LB irradiated on the target area TA to enter the target area TA at a different time than the laser beam LB. Each of the plurality of first additional droplets AD and each of the plurality of second additional droplets AD may enter the target area TA between the plurality of main droplets MD, but embodiments are not limited thereto, and the plurality of first additional droplets AD and the plurality of second additional droplets AD may enter the target area TA between the plurality of main droplets MD.

The debris DE from the plurality of main droplets MD generated from the plurality of main droplets MD being sequentially struck by the laser beam LB in the target area TA may sequentially pass through the target area TA, adsorbed on the plurality of first additional droplets AD and the plurality of second additional droplets AD, to the target area TA together with the plurality of first additional droplets AD and the plurality of second additional droplets AD.

According to one or more example embodiments, the first additional droplet AD and the second additional droplet AD may collide with each other and enter the target area TA. The first additional droplet AD and the second additional droplet AD may collide with each other in the target area TA, but are not limited thereto, and the first additional droplet AD and the second additional droplet AD may collide with each other outside the target area TA and then enter the target area TA. The second additional droplet AD may collide with the first additional droplet AD and enter the target area TA. The second additional droplet AD may collide with the first additional droplet AD in the target area TA.

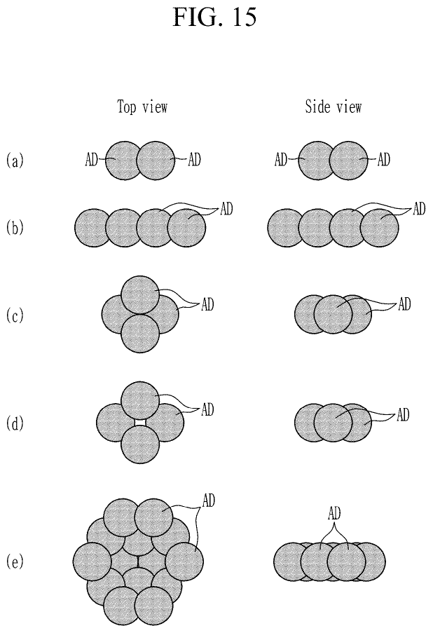

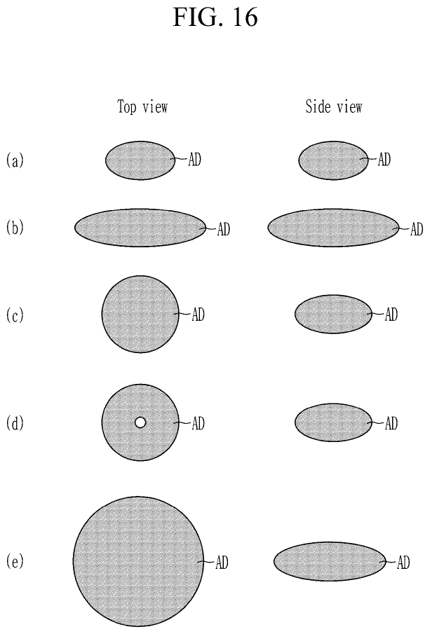

FIG. 15 is a diagram illustrating top and side views showing examples of collisions between a first additional droplet AD and a second additional droplet AD in an EUV lithography apparatus according to embodiments. FIG. 16 is a diagram illustrating top and side views showing examples of additional droplets AD formed after a first additional droplet AD and a second additional droplet AD collide in an EUV lithography apparatus according to one or more example embodiments.

Referring to FIGS. 15 and 16, the first additional droplet AD and the second additional droplet AD collide with each other and may adsorb debris DE in the target area TA in an expanded form.

According to one or more example embodiments, referring to FIG. 15(a) and FIG. 16 (a), the first additional droplet AD and the second additional droplet AD collide with each other to form a circular droplet in a planar and lateral direction, and may adsorb debris DE in the target area TA.

According to one or more example embodiments, referring to FIGS. 15(b) and 16 (b), a plurality of first additional droplets AD and a plurality of second additional droplets AD collide with each other to adsorb debris DE in the target area TA into planar and laterally elliptical droplets.

According to one or more example embodiments, referring to FIG. 15(c) and FIG. 16 (c), a plurality of first additional droplets AD and a plurality of second additional droplets AD collide with each other to adsorb debris DE in the target area TA into droplets that are circular and elliptical droplets.

According to one or more example embodiments, referring to FIGS. 15(d) and 16 (d), a plurality of first additional droplets AD and a plurality of second additional droplets AD may collide with each other to adsorb debris DE in the target area TA into droplets that are planarly ring-shaped and laterally elliptical.

According to one or more example embodiments, referring to FIGS. 15(e) and 16 (e), a plurality of first additional droplets AD and a plurality of second additional droplets AD may collide with each other to adsorb debris DE in the target area TA into droplets that are circular in a planar shape and laterally elliptical.

The first additional droplet AD and the second additional droplet AD may adsorb the debris DE separated from the main droplet MD that generated the plasma PL, thereby suppressing the debris DE from contaminating the mirror.

According to one or more example embodiments, by adsorbing the debris DE separated from the main droplet MD that generated the plasma PL with the first additional droplet AD, it may be possible to suppress the debris DE from contaminating the mirror, optical system, mask, and wafer.

Additionally, the first additional droplet AD may absorb the debris DE separated from the previous main droplet MD that generated plasma in the target area TA, passing through the target area TA. Therefore, one or more example embodiments may suppress the loss of extreme ultraviolet light generated from the plasma generated from the next main droplet MD in the target area TA, which may be absorbed by the debris DE.

According to one or more example embodiments, an EUV light source and an EUV lithography apparatus including the EUV light source may be provided, in which the mirror may be suppressed from being contaminated by the debris DE from the main droplet MD, and at the same time, the loss of extreme ultraviolet light due to the debris DE from the main droplet MD may be suppressed.

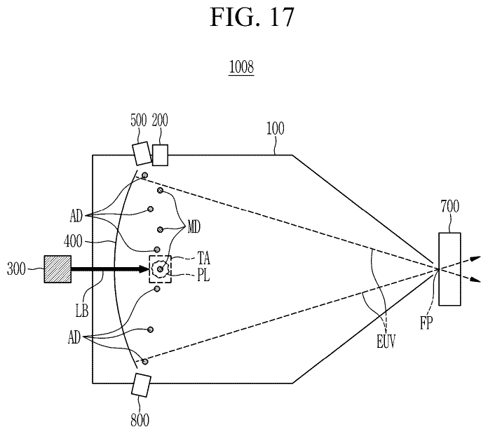

An EUV lithography apparatus according to one or more example embodiments will be described with reference to FIG. 17.

Below, parts that are different from the EUV lithography apparatus according to the above-described one or more example embodiments will be described.

FIG. 17 is a diagram showing an EUV lithography apparatus according to one or more example embodiments.

Referring to FIG. 17, an EUV lithography apparatus 1008 according to one or more example embodiments includes a vacuum chamber 100, a main generator 200, a laser source 300, a mirror 400, a first additional generator 500, a droplet catcher 600, an optical system 700, and a second additional generator 800.

The second additional generator 800 may be spaced apart from the main generator 200 and the first additional generator 500 with the target area TA in between. The drop direction of the second additional droplet AD dropped from the second additional generator 800 into the target area TA may be the drop direction of the main droplet from the first additional generator 500 into the target area TA, but embodiments are not limited thereto.

The second additional generator 800 may drop the second additional droplet AD into the target area TA of the vacuum chamber 100. The second additional generator 800 may include various nozzles to spray a plurality of second additional droplets AD in the form of a droplet stream into the target area TA of the vacuum chamber 100, but embodiments are not limited thereto. The second additional droplet AD entering the target area TA from the second additional generator 800 may enter the target area TA at a different time from the main droplet MD entering the target area TA from the main generator 200. The second additional droplet AD entering the target area TA from the second additional generator 800 may not be struck by the laser beam LB emitted from the laser source 300 and may pass through the target area TA.

The debris DE from the main droplet MD generated from the main droplet MD being struck by the laser beam LB in the target area TA may be attached to the second additional droplet AD passing through the target area TA, and it may be adsorbed and pass through the target area TA together with the second additional droplet AD. According to one or more example embodiments, the second additional droplet AD dropped from the second additional generator 800 into the target area TA may be irradiated on the target area TA in synchronization with the laser beam LB irradiated from the laser source 300, and the second additional droplet AD may enter the target area TA at a time different from that of the laser beam LB, but embodiments are not limited thereto. The second additional droplet AD dropped from the second additional generator 800 may include the same tin as the main droplet MD, but embodiments are not limited thereto, and the second additional droplet AD may comprise a different material than the main droplet MD.

According to one or more example embodiments, the second additional droplet AD may include at least one of polymer, plastic, glass, quartz, dielectric material, semiconductor, silicon, germanium, ceramic, metal, and metal alloy.

According to one or more example embodiments, the second additional droplet AD may include at least one of a metal (e.g., alloy) and a non-metal (e.g., glass, polymer, ceramic) that is in a solid state at room temperature.

According to one or more example embodiments, the second additional droplet AD may include at least one of metals and ceramics including gold, silver, copper, aluminum, etc.

According to one or more example embodiments, the second additional generator 800 may include a plurality of second additional generators 800.

Each of the plurality of second additional generators 800 may be located in different parts of the vacuum chamber 100 to drop a plurality of second additional droplets AD into the target area TA.

The vacuum chamber 100, the main generator 200, the laser source 300, the mirror 400, the first additional generator 500, and the second additional generator 800 are EUV light sources that generate extreme ultraviolet light EUV, but embodiments are not limited thereto. The EUV light source may include a vacuum chamber 100, a main generator 200, a laser source 300, a mirror 400, a first additional generator 500, and a second additional generator 800.

The debris DE from the plurality of main droplets MD generated from the plurality of main droplets MD being sequentially struck by the laser beam LB in the target area TA may sequentially pass through the target area TA adsorbed on the plurality of first additional droplets AD and the plurality of second additional droplets AD into the target area TA together with the plurality of first additional droplets AD and the plurality of second additional droplets AD.

The first additional droplet AD and the second additional droplet AD may adsorb the debris DE separated from the main droplet MD that generated the plasma PL, thereby suppressing the debris DE from contaminating the mirror.

According to one or more example embodiments, the first additional droplet AD may adsorb the debris DE separated from the main droplet MD that generated the plasma PL, thereby suppressing the debris DE from contaminating the mirror, optical system, mask, and wafer.

In addition, the first additional droplet AD and the second additional droplet AD may adsorb debris DE separated from the previous main droplet MD that generated plasma in the target area TA from the target area TA, and the extreme ultraviolet light generated from the plasma generated from the next main droplet MD in the target area TA may be suppressed from being absorbed by the debris DE and lost.

In one or more example embodiments, an EUV light source is provided in which the mirror may be suppressed from being contaminated by debris DE in the main droplet MD and at the same time extreme ultraviolet light may be suppressed from being lost by debris DE in the main droplet MD, and an EUV lithography apparatus is provided including the EUV light source.

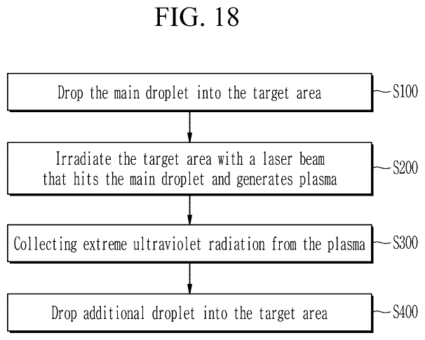

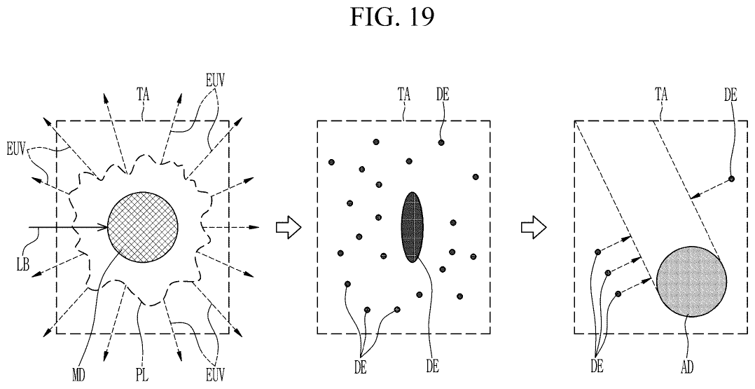

Hereinafter, an EUV light-generation method according to one or more example embodiments will be described with reference to FIGS. 18 and 19.

The EUV light-generation method according to one or more example embodiments may be performed using the above-described EUV light source and an EUV lithography apparatus including the EUV light source, but embodiments are not limited thereto.

FIG. 18 is a flowchart showing an EUV light-generation method according to one or more example embodiments. FIG. 19 is a diagram showing an EUV light-generation method according to one or more example embodiments.

Referring to FIGS. 18 and 19, the main droplet MD may be dropped into the target area TA at operation S100.

Specifically, the main droplet MD may be dropped into the target area TA and may enter the target area TA.

Next, the laser beam LB, which strikes the main droplet MD and generates plasma PL, may be irradiated on the target area TA at operation S200.

Specifically, the main droplet MD that may be dropped into the target area TA and may enter the target area TA may be struck by the laser beam LB irradiated on the target area TA to generate plasma PL.

Next, extreme ultraviolet light EUV generated from the plasma PL may be focused at operation S300.

Specifically, extreme ultraviolet light EUV generated from the plasma PL may be emitted outside the target area TA and may be focused by a mirror.

Next, additional droplets AD are dropped into the target area TA at operation S400.

Specifically, the additional droplet AD may be dropped into the target area TA and may enter the target area TA at a different time than the main droplet MD. Additional droplets AD adsorb debris DE separated from the main droplet MD struck by the laser beam LB. The debris DE of the main droplet MD remains in the target area TA due to the impact of the main droplet MD being struck by the laser beam LB in the target area TA. The additional droplet AD, which may be dropped into the target area TA and may enter the target area TA at a different time than the main droplet MD, may adsorbs the debris DE located in the target area TA and may remove the debris DE and may pass through the target area TA.

According to one or more example embodiments, the debris DE of the main droplet MD may be located outside the target area TA, and the additional droplet AD may pass through the outside of the target area TA to adsorb the debris DE located outside the target area TA.

By adsorbing the debris DE separated from the main droplet MD that generated the plasma PL by the additional droplet AD, the debris DE may be suppressed from contaminating the mirror.

According to one or more example embodiments, the additional droplet AD adsorbs the debris DE separated from the main droplet MD that generated the plasma PL, thereby suppressing the debris DE from contaminating the mirror, optical system, mask, and wafer.

The additional droplet AD may absorb the debris DE separated from the previous main droplet MD, which generated plasma PL in the target area TA and may pass through the target area TA, and the extreme ultraviolet light EUV generated by the plasma generated by the next main droplet MD in the target area TA may be absorbed by the debris DE and lost.

According to one or more example embodiments, an EUV light-generation method is provided, which suppresses the contamination of the mirror by the residue of the main droplet MD and simultaneously suppresses the loss of EUV light due to the debris DE from the main droplet MD.

Although one or more example embodiments have been described in detail above, the scope of the present disclosure is not limited thereto, and it will be apparent to those skilled in the art that various modifications and improvements may be made therein without departing from the spirit and scope of the following claims.

What is claimed is:

1. An extreme ultraviolet light (EUV) light source comprising:
a vacuum chamber comprising a target area;
a main generator configured to drop a main droplet into the target area;
a laser source configured to irradiate, to the target area, a laser beam that strikes the main droplet to generate plasma;
a mirror adjacent to the target area and configured to concentrate extreme ultraviolet rays generated from the plasma; and
a first additional generator adjacent to the main generator and configured to drop a first additional droplet into the target area.

2. The EUV light source of claim 1, wherein the EUV light source is configured such that the first additional droplet enters the target area at a different time than the main droplet.

3. The EUV light source of claim 2, wherein the main droplet comprises a plurality of main droplets,
wherein the first additional droplet comprises a plurality of first additional droplets, and
wherein each of the plurality of first additional droplets enters the target area between ones of the plurality of main droplets.

4. The EUV light source of claim 2, wherein the EUV light source is configured such that the first additional droplet is not struck by the laser beam.

5. The EUV light source of claim 1, wherein the EUV light source is configured such that a first entry direction of the first additional droplet entering the target area is different from a main entry direction of the main droplet entering the target area.

6. The EUV light source of claim 1, wherein each of the main droplet and the first additional droplet comprises tin.

7. The EUV light source of claim 1, wherein the first additional droplet comprises a material different from a material of the main droplet.

8. The EUV light source of claim 1, wherein a diameter of the first additional droplet is smaller than a diameter of the main droplet.

9. The EUV light source of claim 1, wherein a diameter of the first additional droplet is larger than a diameter of the main droplet.

10. The EUV light source of claim 1, wherein the first additional droplet comprises:
a core comprising a material that is different from a material of the main droplet; and
a shell that surrounds the core and has a higher adsorption capacity for the main droplet than the core.

11. The EUV light source of claim 10, wherein the first additional droplet further comprises an intermediate layer provided between the core and the shell.

12. The EUV light source of claim 1, further comprising:
a second additional generator adjacent to the main generator and configured to drop a second additional droplet into the target area.

13. The EUV light source of claim 12, wherein the EUV light source is configured such that the second additional droplet collides with the first additional droplet and enters the target area.

14. The EUV light source of claim 13, wherein the EUV light source is configured such that the second additional droplet collides with the first additional droplet in the target area.

15. An extreme ultraviolet light (EUV) lithography apparatus comprising:
a vacuum chamber comprising a target area;
a main generator configured to drop a main droplet into the target area;
a laser source configured to irradiate, to the target area, a laser beam that strikes the main droplet to generate plasma;
a mirror adjacent to the target area and configured to concentrate extreme ultraviolet rays, generated from the plasma, to a focusing point;
an additional generator adjacent to the main generator and configured to drop an additional droplet into the target area; and
an optical system provided at the focusing point.

16. The EUV lithography apparatus of claim 15, wherein the EUV lithography apparatus is configured such that the additional droplet enters the target area at a different time than the main droplet.

17. The EUV lithography apparatus of claim 15, wherein the EUV lithography apparatus is configured such that an entry direction of the additional droplet entering the target area is different from an entry direction of the main droplet entering the target area.

18. A method of extreme ultraviolet light (EUV) light generation, the method comprising:
dropping a main droplet into a target area;
irradiating, to the target area, a laser beam that strikes the main droplet to generate plasma;
concentrating extreme ultraviolet rays generated from the plasma; and
dropping an additional droplet into the target area.

19. The method of EUV light generation of claim 18, wherein the dropping the additional droplet into the target area comprises dropping the additional droplet into the target area at a different time than the main droplet.

20. The method of EUV light generation of claim 18, wherein the dropping the additional droplet into the target area comprises adsorbing, by the additional droplet, debris separated from the main droplet struck by the laser beam.
